(19) United States
(12) Patent Application Publication
(10) Pub. No.: US 2021/0351382 A1
(43) Pub. Date: Nov. 11, 2021

(54) DISPLAY DEVICE AND ELECTRONIC EQUIPMENT

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yicheng CHEN, Wuhan, Hubei (CN)

(21) Appl. No.: 16/963,516

(22) PCT Filed: Jun. 19, 2020
(86) PCT No.: PCT/CN2020/096965

§ 371 Date: Jul. 21, 2020

(30) Foreign Application Priority Data
May 7, 2020 (CN) 202010378617.2

(51) Int. Cl. H01L 51/52; H01L 27/32

(52) U.S. Cl. CPC H01L 51/5281; H01L 27/3272

(57) ABSTRACT

The present application provides a display device and an electronic equipment, including a display functional layer, a polarizer, an optical adhesive layer, and a cover plate, which are disposed in sequence. The display functional layer includes a light-transmitting region. The polarizer is provided with an opening. The opening corresponds to the light-transmitting region. The optical adhesive layer is filled in the opening. A surface of the polarizer facing the opening is a buffer surface. A portion of the optical adhesive layer in the opening is attached to the buffer surface.

### FIELD OF THE INVENTION

The present application is related to the field of display technology, and specifically, to a display device and an electronic equipment.

### BACKGROUND OF THE INVENTION

With development of display technology, organic light-emitting diode (OLED) screens punched with openings have become a mainstream screen design of markets.

However, when a cover plate is attached to a polarizer above an opening punched on a display panel through an optical adhesive, due to a gradient difference between the polarizer and the optical adhesive, the optical adhesive cannot completely fill the opening on the polarizer. A gap is generated at a position where a wall of the opening of the polarizer and the optical adhesive is attached, resulting in a presence of bubbles in the opening of the polarizer, which further reduces an optical performance of a display device.

### SUMMARY OF THE INVENTION

The present application provides a display device and an electronic equipment to solve a technical problem of a presence of bubbles in an opening of the polarizer after a cover plate attached to a display panel.

The present application provides a display device including:

a display functional layer being an organic light-emitting diode display layer and including a light-transmitting region, wherein the light-transmitting region is configured to pass light required by an electronic device;

a polarizer disposed on the display functional layer and provided with an opening, wherein the opening coaxially corresponds to the light-transmitting region;

an optical adhesive layer disposed on the polarizer and filled in the opening; and

a cover plate disposed on the optical adhesive layer;

wherein a surface of the polarizer facing the opening is a buffer surface, and a portion of the optical adhesive layer in the opening is attached to the buffer surface.

In the display device of the preset application, the buffer surface includes a first end and a second end, and the second end is an end of the buffer surface near the light-transmitting region; and

a distance between the buffer surface and a boundary of the light-transmitting region progressively decreases from the first end to the second end.

In the display device of the preset application, the buffer surface is a convex surface.

In the display device of the preset application, the convex surface is an arc surface, the arc surface includes a midline, and the midline extends along a circumferential direction of the arc surface; and

an angle between a tangent plane of the arc surface passing through the midline and a plane where the display functional layer is located ranges from 30 degrees to 90 degrees.

In the display device of the preset application, the buffer surface is a flat surface.

In the display device of the preset application, a preset distance b is provided between the first end and the second end in a direction parallel to a plane where the display functional layer is located, and 0.2 mm≤b≤0.3 mm.

In the display device of the preset application, the display functional layer includes a light-shielding region, the light-shielding region is disposed around the light-transmitting region, and an orthographic projection of the buffer surface on a plane where the display functional layer is located is in the light-shielding region.

The present application further provides a display device including:

a display functional layer including a light-transmitting region, wherein the light-transmitting region is configured to pass light required by an electronic device;

a polarizer disposed on the display functional layer and provided with an opening, wherein the opening corresponds to the light-transmitting region;

an optical adhesive layer disposed on the polarizer and filled in the opening; and

a cover plate disposed on the optical adhesive layer;

wherein a surface of the polarizer facing the opening is a buffer surface, and a portion of the optical adhesive layer in the opening is attached to the buffer surface.

In the display device of the preset application, the buffer surface includes a first end and a second end, and the second end is an end of the buffer surface near the light-transmitting region; and

a distance between the buffer surface and a boundary of the light-transmitting region progressively decreases from the first end to the second end.

In the display device of the preset application, the buffer surface is a convex surface.

In the display device of the preset application, the convex surface is an arc surface, the arc surface includes a midline, and the midline extends along a circumferential direction of the arc surface; and

an angle between a tangent plane of the arc surface passing through the midline and a plane where the display functional layer is located ranges from 30 degrees to 90 degrees.

In the display device of the preset application, the buffer surface is a flat surface.

In the display device of the preset application, a preset distance b is provided between the first end and the second end in a direction parallel to a plane where the display functional layer is located, and 0.2 mm≤b≤0.3 mm.

In the display device of the preset application, the display functional layer includes a light-shielding region, the light-shielding region is disposed around the light-transmitting region, and an orthographic projection of the buffer surface on a plane where the display functional layer is located is in the light-shielding region.

In the display device of the preset application, the opening coaxially corresponds to the light-transmitting region.

In the display device of the preset application, the display functional layer is an organic light-emitting diode display layer.

The present application further provides an electronic equipment including a display device, and the display device includes:

a display functional layer including a light-transmitting region, wherein the light-transmitting region is configured to pass light required by an electronic device;

a polarizer disposed on the display functional layer and provided with an opening, wherein the opening corresponds to the light-transmitting region;

an optical adhesive layer disposed on the polarizer and filled in the opening; and

a cover plate disposed on the optical adhesive layer;

wherein a surface of the polarizer facing the opening is a buffer surface, and a portion of the optical adhesive layer in the opening is attached to the buffer surface.

In the electronic equipment of the preset application, the buffer surface includes a first end and a second end, and the second end is an end of the buffer surface near the light-transmitting region; and

a distance between the buffer surface and a boundary of the light-transmitting region progressively decreases from the first end to the second end.

In the electronic equipment of the preset application, the buffer surface is a convex surface.

In the electronic equipment of the preset application, the convex surface is an arc surface, the arc surface includes a midline, and the midline extends along a circumferential direction of the arc surface; and

an angle between a tangent plane of the arc surface passing through the midline and a plane where the display functional layer is located ranges from 30 degrees to 90 degrees.

Compared with a display device in the prior art, the display device provided by the present application configures the surface of the polarizer facing the opening as the buffer surface and attaches the portion of the optical adhesive layer in the opening to the buffer surface, so after the cover plate is attached to the polarizer on the display functional layer, the bubbles present in the opening of the polarizer are completely eliminated, thereby increasing an optical performance of the display device.

### DESCRIPTION OF DRAWINGS

In order to describe technical solutions in the present application clearly, drawings to be used in the description of embodiments will be described briefly below. Obviously, drawings described below are only for some embodiments of the present application, and other drawings may be obtained by those skilled in the art based on these drawings without creative efforts.

FIG. 1 is a schematic plan structural diagram of a display device provided by an embodiment of the present application.

FIG. 2 is a schematic structural diagram of a cross-sectional view along line AA′ in FIG. 1.

FIG. 3 is a schematic structural diagram of a first cross-sectional view of a polarizer in the display device provided by an embodiment of the present application.

FIG. 4 is a schematic structural diagram of a second cross-sectional view of a polarizer in the display device provided by an embodiment of the present application.

### DETAILED DESCRIPTION OF PREFERRED EMBODIMENTS

The technical solution of the present application embodiment will be clarified and completely described with reference accompanying drawings in embodiments of the present application embodiment. Obviously, the present application described parts of embodiments instead of all of the embodiments. Based on the embodiments of the present application, other embodiments which can be obtained by a skilled in the art without creative efforts fall into the protected scope of the of the present application.

In the description of the present application, it should be noted that the terms “center”, “portrait”, “transverse”, “length”, “width”, “thickness”, “upper”, “lower”, “front”, the directions or positional relationships indicated by “back”, “left”, “right”, “vertical”, “horizontal”, “top”, “bottom”, “inside”, “outside”, etc. are based on the drawings. The orientation or positional relationship is only for the convenience of describing the present application and simplifying the description, and does not indicate or imply that the device or element referred to must have a specific orientation, structure and operation in a specific orientation, and should not be viewed as limitations of the present application. In addition, terms “first” and “second” are used for descriptive purposes only, and cannot be understood as indicating or implying relative importance or implicitly indicating the number of technical features indicated. Therefore, the features defined as “first” and “second” may explicitly or implicitly include one or more of the features. In the description of the present application, the meaning of “multiple” is two or more, unless specifically defined otherwise.

In the description of the present application, it should be noted that terms “installation”, “link”, and “connection” should be understood broadly, unless explicitly stated and limited otherwise. For example, connection can be fixed connection or removable or integral connection, can be mechanical connection, electrical connection or mutual communication, can be direct connection or indirect connection through an intermedium, or can be the internal communication between two components or the mutual reaction between two components. For a skilled person in the art, the specific meanings of the above terms of the present application can be understood according to practical situations.

In the present application, unless explicitly stated and limited, the first feature is “on” or “under” the second feature may refer to that the first feature and second feature are directly contact, or are indirectly through another feature between them. Moreover, the first feature is “above”, “upon”, and “upper” the second feature, including that the first feature is directly above and obliquely above the second feature refers to that t the first feature is higher in level than the second feature. The first feature is “below”, “down”, and “under” of the second feature refers to that the first feature is directly below or obliquely below the second feature, or merely refers to that the first feature is horizontally lower than the second feature.

The following application provides many different embodiments or examples for implementing different structures of the present application. To simplify the application of the present application, the components and settings of specific examples are described below. Obviously, these are merely examples instead of limitation of the present application. Furthermore, the present application may repeat reference numbers and/or reference letters in different examples, and such repetition is for the purpose of simplicity and clarity, and does not indicate the relationship between the various embodiments and/or settings.

It should be explained that an electronic device in the present application can be a camera assembly or other sensor devices, such as a distance sensor and a light sensor, which is not limited in the present application.

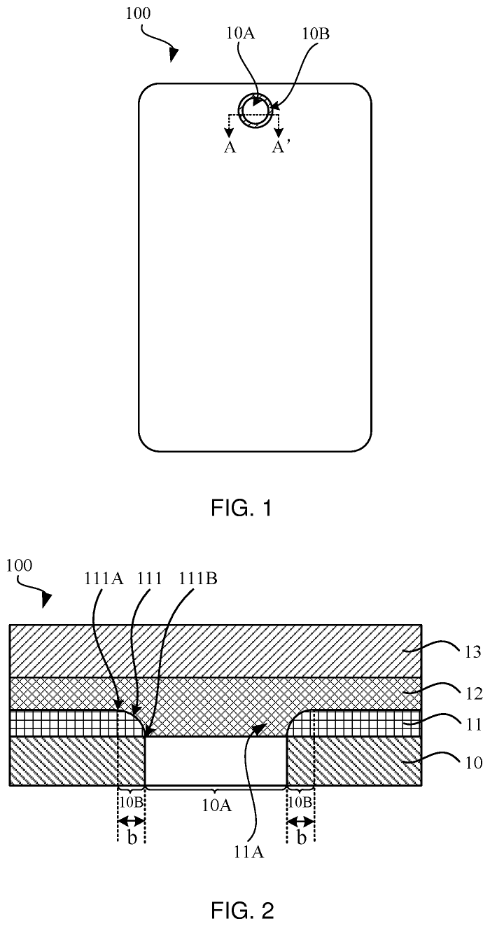

Please refer to FIGS. 1 and 2. FIG. 1 is a schematic plan structural diagram of a display device provided by an embodiment of the present application, and FIG. 2 is a schematic structural diagram of a cross-sectional view along line AA′ in FIG. 1.

The display device 100 provided by an embodiment of the present application includes a display functional layer 10, a polarizer 11, an optical adhesive layer 12, and a cover plate 13. The display functional layer 10 includes a light-transmitting region 10A. The light-transmitting region 10A is configured to pass light required by an electronic device. The polarizer 11 is disposed on the display functional layer 11. The polarizer 11 is provided with an opening 11A. The opening 11A corresponds to the light-transmitting region 10A. The optical adhesive layer 12 is disposed on the polarizer 11. The optical adhesive layer 12 is filled in the opening 11A. The cover plate 13 is disposed on the optical adhesive layer 12. A surface of the polarizer 11 facing the opening 11A is a buffer surface 111. A portion of the optical adhesive layer 12 in the opening 11A is attached to the buffer surface 111.

Thus, the display device 100 of an embodiment of the present application configures the surface of the polarizer 11 facing the opening 11A as the buffer surface 11 and attaches the portion of the optical adhesive layer 12 in the opening 11A to the buffer surface 111. A buffering effect of the buffer surface 111 relieves an influence of a gradient difference of the polarizer 11. After the cover plate 13 is attached to the polarizer 11 through the optical adhesive layer 12, a wall of the opening 11A of the polarizer 11 and the optical adhesive layer 12 form a tight attachment, which eliminates bubbles generated due to a gap between surfaces to be attached, thereby increasing an optical performance of the display device.

It should be explained that the display functional layer 10 in the present application can be a liquid crystal display layer or an organic light-emitting diode display layer. In an embodiment of the present application, the display functional layer 10 is an organic light-emitting diode display layer.

In an embodiment of the present application, the opening 11A coaxially corresponds to the light-transmitting region 10A. In addition, A specific positional relationship between the opening 11A and the light-transmitting region 10A can also be configured according to an actual situation, which is not limited in the present application. Also, a specific position and a structure of the light-transmitting region 10A can both refer to the prior art and are not repeated herein.

In an embodiment of the present application, the buffer surface 111 includes a first end 111A and a second end 111B. The second end 111B is an end of the buffer surface 111 near the light-transmitting region 10A. A distance between the buffer surface 111 and a boundary of the light-transmitting region 10A progressively decreases from the first end 111A to the second end 111B.

Understandably, a method of attaching the cover plate 13 to the display functional layer 10 is as follows. First, the display functional layer 10 is provided, and the polarizer 11 is disposed on a light-emitting surface of the display functional layer 10. Next, an optical adhesive is coated on the cover plate 13 to obtain the optical adhesive layer 12, which is uncured. Then, a surface of the cover plate 13 coated with the uncured optical adhesive layer 12 is attached to the polarizer 11 on the display functional layer 10. Finally, the uncured optical adhesive layer 12 is cured to complete an attachment between the display functional layer 10 and the cover plate 13.

Therefore, when the cover plate 13 coated with the uncured optical adhesive layer 12 is attached to the polarizer 11, the optical adhesive in the optical adhesive layer 12 is squeezed into the opening 11A of the polarizer 11. In this embodiment, the distance between the buffer surface 111 and the boundary of the light-transmitting region 10A progressively decreases from the first end 111A to the second end 111 B, thereby relieving the influence of the gradient difference of the polarizer 11. The optical adhesive squeezed into the opening 11A can completely fill the opening 11A, which prevents a position where a wall of the opening of the polarizer and the optical adhesive is attached from generating a gap, thereby eliminating a possibility of bubbles present in the opening 11A of the polarizer 11.

In an embodiment of the present application, the buffer surface 111 is a convex surface. The convex surface can be formed by a laser process or other cutting processes. The specific method of forming the convex surface can be selected according to an actual process condition, which is not limited in the present application.

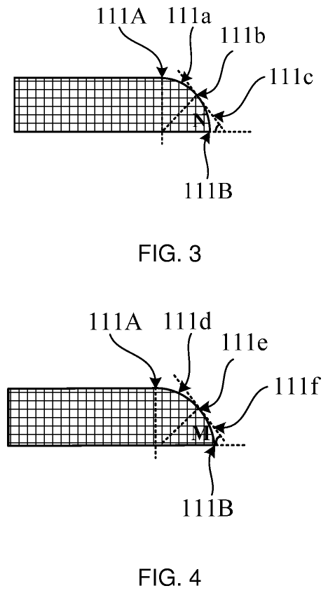

Further, please refer to FIG. 3, which is a schematic structural diagram of a first cross-sectional view of the polarizer in the display device provided by an embodiment of the present application.

In an embodiment of the present application, the convex surface is an arc surface. The arc surface includes a midline (not shown). The midline extends along a circumferential direction of the arc surface. An angle between a tangent plane of the arc surface passing through the midline and a plane where the display functional layer 10 is located ranges from 30 degrees to 90 degrees.

It should be explained that the midline of the arc surface in the present application is not the midline in a mathematical sense. In an embodiment of the present application, the midline of the arc surface is defined as a midline between the first end 111A and the second end 111B of the arc surface. Specifically, along a curved direction of the arc surface, a curve distance between any point on the midline and a corresponding point on the first end 111A is same as a curve distance between a corresponding point on the second end 111B.

Understandably, in order to facilitate description of this embodiment, the present application takes a cross-sectional structure of the arc surface as an example for description, but it cannot be understood as a limitation to the present application.

Specifically, as shown in FIG. 3, the arc surface includes an arc line 111a. The midline includes a midpoint 111b. Along the circumferential direction of the arc surface, countless midpoints 111b form the midline. A tangent plane of the arc surface passing through the midline includes a tangent line 111c. Therefore, the angle between the tangent plane of the arc surface passing through the midline and the plane where the display functional layer 10 is located is: an acute angle N formed between the tangent line 111c at the midpoint 111b on the arc line 111a and the plane where the display functional layer 10 is located. The angle N ranges from 30 degrees to 90 degrees (excluding 30 degrees and 90 degrees).

Understandably, within the above range, the wall of the opening 11A of the polarizer 11 and the optical adhesive can have a good attaching effect. Specifically, in this embodiment, a value of N can be configured to 35 degrees, 40 degrees, 50 degrees, 60 degrees, 80 degrees, or 85 degrees, etc. The specific value of N can be configured according to an actual situation, which is not limited in the present application.

It should be explained that the value of N also depends on a thickness of the polarizer 11. In some embodiments, a buffering effect of the buffer surface 111 can be configured by adjusting the thickness of the polarizer 11, which is not repeated herein.

Please refer to FIG. 4, which is a schematic structural diagram of a second cross-sectional view of the polarizer in the display device provided by an embodiment of the present application.

Specifically, the convex surface is a non-arc surface. The non-arc surface includes a circumferential line (not shown). The circumferential line extends along a circumferential direction of the non-arc surface. An angle between a tangent plane of the non-arc surface passing through the circumferential line and the plane where the display functional layer 10 is located ranges from 30 degrees to 90 degrees.

It should be explained that the circumferential line of the non-arc surface in the present application is defined as a circumferential line between the first end 111A and the second end 111B. Specifically, on the non-arc surface, points on each non-arc line with a maximum curvature are connected to each other along the circumferential direction of the non-arc surface to form the circumferential line.

Specifically, as shown in FIG. 4, the non-arc surface includes the non-arc line 111d. The circumferential line includes a tangent point 111e. The tangent point 111e is a point having a maximum curvature on the non-arc line 111d. Along the circumferential direction of the non-arc surface, countless tangent points 111e form the circumferential line. A tangent plane of the non-arc surface passing through the circumferential line includes a tangent line 111f. Therefore, the angle between the tangent plane of the non-arc surface passing through the circumferential line and the plane where the display functional layer 10 is located is: an acute angle M formed between the tangent line 111f at the tangent point 111e on the non-arc line 111d and the plane where the display functional layer 10 is located. The angle M ranges from 30 degrees to 90 degrees (excluding 30 degrees and 90 degrees).

Understandably, within the above range, the wall of the opening 11A of the polarizer 11 and the optical adhesive can have a good attaching effect. Specifically, in this embodiment, a value of M can be configured to 35 degrees, 40 degrees, 50 degrees, 60 degrees, 80 degrees, or 85 degrees, etc. The specific value of M can be configured according to an actual situation, which is not limited in the present application.

It should be explained that the value of M also depends on the thickness of the polarizer 11. In some embodiments, the buffering effect of the buffer surface 111 can be configured by adjusting the thickness of the polarizer 11, which is not repeated herein.

In some embodiments, the buffer surface 111 can be a flat surface. An angle between the flat surface and the plane where the display functional layer is located ranges from 30 degrees to 90 degrees (excluding 30 degrees and 90 degrees), which is not repeated herein.

It should be explained that the convex surface in the present application can also be a convex structure formed by a plurality of planes connected to each other, or can also be a combination of a plurality of planes and curved surfaces, and so on. The present application does not specifically limit a specific structure of the convex surface, and any design of the convex structure having a buffering effect is within a scope of protection of the present application.

Please continue to refer to FIG. 2. Furthermore, in an embodiment of the present application, a preset distance b is provided between the first end 111A and the second end 111B in a direction parallel to a plane where the display functional layer 10 is located, and 0.2 mm≤b≤0.3 mm. Within the above range, the optical adhesive layer 12 and the wall of the opening 11A of the polarizer 11 have an excellent attaching effect. The optical adhesive is enabled to fill the gap generated at an attachment position effectively, thereby further reducing a possibility of the bubbles generated in the opening 11A due to a poor attaching effect of the optical adhesive layer 12.

Specifically, in this embodiment, a value of b can be configured to 0.2 mm, 0.25 mm, or 0.3 mm, and the specific value of b can be configured according to an actual situation, which is not limited in the present application.

Understandably, within the range of 0.2 mm≤b≤0.3 mm, the greater the value of b is, the better the buffering effect of the buffer surface 111 is. In other words, when b is 0.3 mm, the buffering effect is the best, which makes the optical adhesive and the wall of the opening 11A of the polarizer 11 have a better attaching effect. A filling effect of the optical adhesive is further increased, which greatly reduces a possibility of generating the gap between the optical adhesive and the wall of the openings 11A of the polarizer 11, thereby increasing the optical performance of the display device.

Furthermore, inventors found in a lot of experimental research work that under the above configuration conditions, a structural design in the present application can increase an overall optical performance of the display device by 60% compared to the polarizer structure in the prior art, thereby greatly increasing an performance of a display product and increasing market competitiveness of the display product.

Please continue to refer to FIGS. 1 and 2. Furthermore, the display functional layer 10 includes a light-shielding region 10B. The light-shielding region 10B is disposed around the light-transmitting region 10A. An orthographic projection of the buffer surface 111 on a plane where the display functional layer 10 is located is in the light-shielding region 10B.

Understandably, the light-shielding region 10B is configured to prevent light emitted by the light-emitting element in the display functional layer 10 from entering the light-transmitting region 10A, which affects the light-transmitting effect of the electronic device. A shielding range of the light-shielding region 10B can be configured according to an actual product requirement and process condition, which is not limited in the present application.

In an embodiment of the present application, by making the orthographic projection of the buffer surface 111 on the plane where the display functional layer 10 is located in the light-shielding region 10B, the bubbles generated at the attachment position between the wall 11A of the polarizer 11 and the optical adhesive layer 12 are eliminated. Meanwhile it can also ensure a display effect of a display region around the opening 11A of the polarizer 11 and prevent the display effect of the display region around the opening 11A from being affected by a design of the buffer surface 111.

It should be explained that the orthographic projection of the buffer surface 111 on the plane where the display functional layer 10 is located in the present application can fall within the light-shielding region 10B, or can overlap the light-shielding region 10B. This embodiment only takes the orthogonal projection of the buffer surface 111 on the plane where the display functional layer 10 is located overlapping with the light-shielding region 10B as an example for description, but it cannot be understood as a limitation to the present application.

The display device 100 provided by an embodiment of the present application configures the surface of the polarizer 11 facing the opening 11A as the buffer surface 111 and attaches the portion of the optical adhesive layer 12 in the opening 11A to the buffer surface 111. The buffering effect of the buffer surface 111 relieves the influence of the gradient difference of the polarizer 11. After the cover plate 13 is attached to the polarizer 11 through the optical adhesive layer 12, the wall of the opening 11A of the polarizer 11 and the optical adhesive layer 12 form a tight attachment, which eliminates the bubbles generated due to the gap between surfaces to be attached, thereby increasing the optical performance of the display device.

An embodiment of the present application also provides an electronic equipment. Specifically, the electronic equipment can be a mobile phone, a laptop, or a tablet. The electronic equipment includes the display device 100 in the foregoing embodiments. Specifically, for a specific structure of the display device 100, reference can be made to the description in the foregoing embodiments, and details are not described herein again.

Compared with a display device in the prior art, the display device provided by the present application configures the surface of the polarizer facing the opening as the buffer surface and attaches the portion of the optical adhesive layer in the opening to the buffer surface, so after the cover plate is attached to the polarizer on the display functional layer, the bubbles present in the opening of the polarizer are completely eliminated, thereby increasing the optical performance of the display device.

Embodiments provided by the present application are described in detail above, the specific examples of this document are used to explain principles and embodiments of the present application, and the description of embodiments above is only for helping to understand the present disclosure. Meanwhile, those skilled in the art will be able to change the specific embodiments and the scope of the disclosure according to the idea of the present application. In the above, the content of the specification should not be construed as limiting the present application. Above all, the content of the specification should not be the limitation of the present application.

What is claimed is:

1. A display device, comprising:
a display functional layer being an organic light-emitting diode display layer and comprising a light-transmitting region, wherein the light-transmitting region is configured to pass light required by an electronic device;
a polarizer disposed on the display functional layer and provided with an opening, wherein the opening coaxially corresponds to the light-transmitting region;
an optical adhesive layer disposed on the polarizer and filled in the opening; and
a cover plate disposed on the optical adhesive layer;
wherein a surface of the polarizer facing the opening is a buffer surface, and a portion of the optical adhesive layer in the opening is attached to the buffer surface.

2. The display device according to claim 1, wherein the buffer surface comprises a first end and a second end, and the second end is an end of the buffer surface near the light-transmitting region; and
a distance between the buffer surface and a boundary of the light-transmitting region progressively decreases from the first end to the second end.

3. The display device according to claim 2, wherein the buffer surface is a convex surface.

4. The display device according to claim 3, wherein the convex surface is an arc surface, the arc surface comprises a midline, and the midline extends along a circumferential direction of the arc surface; and
an angle between a tangent plane of the arc surface passing through the midline and a plane where the display functional layer is located ranges from 30 degrees to 90 degrees.

5. The display device according to claim 2, wherein the buffer surface is a flat surface.

6. The display device according to claim 2, wherein a preset distance b is provided between the first end and the second end in a direction parallel to a plane where the display functional layer is located, and 0.2 mm≤b≤0.3 mm.

7. The display device according to claim 2, wherein the display functional layer comprises a light-shielding region, the light-shielding region is disposed around the light-transmitting region, and an orthographic projection of the buffer surface on a plane where the display functional layer is located is in the light-shielding region.

8. A display device, comprising:
a display functional layer comprising a light-transmitting region, wherein the light-transmitting region is configured to pass light required by an electronic device;
a polarizer disposed on the display functional layer and provided with an opening, wherein the opening corresponds to the light-transmitting region;
an optical adhesive layer disposed on the polarizer and filled in the opening; and
a cover plate disposed on the optical adhesive layer;
wherein a surface of the polarizer facing the opening is a buffer surface, and a portion of the optical adhesive layer in the opening is attached to the buffer surface.

9. The display device according to claim 8, wherein the buffer surface comprises a first end and a second end, and the second end is an end of the buffer surface near the light-transmitting region; and
a distance between the buffer surface and a boundary of the light-transmitting region progressively decreases from the first end to the second end.

10. The display device according to claim 9, wherein the buffer surface is a convex surface.

11. The display device according to claim 10, wherein the convex surface is an arc surface, the arc surface comprises a midline, and the midline extends along a circumferential direction of the arc surface; and
an angle between a tangent plane of the arc surface passing through the midline and a plane where the display functional layer is located ranges from 30 degrees to 90 degrees.

12. The display device according to claim 9, wherein the buffer surface is a flat surface.

13. The display device according to claim 9, wherein a preset distance b is provided between the first end and the second end in a direction parallel to a plane where the display functional layer is located, and 0.2 mm≤b≤0.3 mm.

14. The display device according to claim 9, wherein the display functional layer comprises a light-shielding region, the light-shielding region is disposed around the light-transmitting region, and an orthographic projection of the buffer surface on a plane where the display functional layer is located is in the light-shielding region.

15. The display device according to claim 8, wherein the opening coaxially corresponds to the light-transmitting region.

16. The display device according to claim 8, wherein the display functional layer is an organic light-emitting diode display layer.

17. A electronic equipment, comprising a display device, wherein the display device comprises:
a display functional layer comprising a light-transmitting region, wherein the light-transmitting region is configured to pass light required by an electronic device;
a polarizer disposed on the display functional layer and provided with an opening, wherein the opening corresponds to the light-transmitting region;
an optical adhesive layer disposed on the polarizer and filled in the opening; and
a cover plate disposed on the optical adhesive layer;
wherein a surface of the polarizer facing the opening is a buffer surface, and a portion of the optical adhesive layer in the opening is attached to the buffer surface.

18. The electronic equipment according to claim 17, wherein the buffer surface comprises a first end and a second end, and the second end is an end of the buffer surface near the light-transmitting region; and
a distance between the buffer surface and a boundary of the light-transmitting region progressively decreases from the first end to the second end.

19. The electronic equipment according to claim 18, wherein the buffer surface is a convex surface.

20. The electronic equipment according to claim 19, wherein the convex surface is an arc surface, the arc surface comprises a midline, and the midline extends along a circumferential direction of the arc surface; and
an angle between a tangent plane of the arc surface passing through the midline and a plane where the display functional layer is located ranges from 30 degrees to 90 degrees.
